(19) United States
(12) Patent Application Publication
(10) Pub. No.: US 2008/0128760 A1
(43) Pub. Date: Jun. 5, 2008

(54) SCHOTTKY BARRIER NANOWIRE FIELD EFFECT TRANSISTOR AND METHOD FOR FABRICATING THE SAME

(75) Inventors: Myungsim Jun, Daejon (KR); Moon-Gyu Jang, Daejon (KR); Yark-Yeon Kim, Daejon (KR); Chel-Jong Choi, Daejon (KR); Taeyoub Kim, Seoul (KR); Seongjae Lee, Daejon (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Electronics and Telecommunications Research Institute, Daejon (KR)

(21) Appl. No.: 11/948,664

(22) Filed: Nov. 30, 2007

(30) Foreign Application Priority Data
Dec. 4, 2006 (KR) 10-2006-0121276
Oct. 5, 2007 (KR) 10-2007-0100558

(51) Int. Cl. H01L 21/338; H01L 29/00

(52) U.S. Cl. 257/280; 438/180; 257/E21.085; 257/E29.169

(57) ABSTRACT

Provided is a Schottky barrier nanowire field effect transistor, which has source/drain electrodes formed of metal silicide and a channel formed of a nanowire, and a method for fabricating the same. The Schottky barrier nanowire field effect transistor includes: a channel suspended over a substrate and including a nanowire; metal silicide source/drain electrodes electrically connected to both ends of the channel over the substrate; a gate electrode disposed to surround the channel; and a gate insulation layer disposed between the channel and the gate electrode.

### CROSS-REFERENCE(S) TO RELATED APPLICATIONS

The present invention claims priority of Korean Patent Application Nos. 10-2006-0121276 and 10-2007-0100558, filed on Dec. 4, 2006, and Oct. 5, 2007, respectively, which are incorporated herein by reference.

### BACKGROUND OF THE INVENTION

1. Field of the Invention

The present invention relates to a semiconductor device and a method for fabricating the same; and, more particularly, to a Schottky barrier nanowire field effect transistor, which has source/drain electrodes formed of metal silicide and a channel formed of a nanowire, and a method for fabricating the same.

This work was supported by the IT R&D program of MIC/IITA [2005-S-104-02, “High-tech semiconductor nano device for information communication”].

2. Description of Related Art

As the integration density of semiconductor devices increases, conventional semiconductor devices are reaching their scaling limits. So far, many methods of scaling the device have been proposed fulfilling the request for low power consumption, high integration, and high speed devices. This trend comes with decreases in an isolation region between unit elements, the width and length of a gate insulation layer, and a junction depth of a source and a drain. Further, transistors have been structurally modified. Examples of the transistors include ultra-thin body fully depleted silicon-on-insulator (UTB-FD SOI) transistors using an SOI substrate, band-engineered transistors using a strained-Si channel to increase electron mobility, vertical transistors, Fin-FETs, and double-gate transistors.

Transistors employing a nano material as a channel have been proposed to overcome scaling limits encountered by silicon-based devices and study new physical phenomenon. A representative transistor is a transistor employing a carbon nano tube (CNT) as a channel. The CNT is a one-dimensional semiconductor that has high electron and hole mobility and exhibits an electric characteristic different from a typical bulk semiconductor. The Dekker group of Delft University of Technology developed a CNT-FET in 1998. The CNT-FET carries out a gate operation at room temperature. Thus, the CNT-FET is considered as a substitute for silicon-based transistors.

Recently, many studies on transistor structures and fabricating methods thereof have been conducted to effectively use characteristics of nano materials such as CNT. In these studies, one technical problem to be solved is to develop a transistor structure which can ensure stability of nano material and excellent operation characteristic, and a method for fabricating the same.

### SUMMARY OF THE INVENTION

An embodiment of the present invention is directed to providing a Schottky barrier nanowire FET using a nanowire as a channel of carriers, and a method for fabricating the same.

Another embodiment of the present invention is directed to provide a Schottky barrier nanowire FET which is easy to fabricate and can ensure thermal stability and have excellent gate controllability, and a method for fabricating the same.

In accordance with an aspect of the present invention, there is provided a Schottky barrier nanowire field effect transistor, which includes: a channel suspended over a substrate and including a nanowire; source/drain electrodes electrically connected to both ends of the channel over the substrate and including metal silicide; a gate electrode disposed to surround the channel; and a gate insulation layer disposed between the channel and the gate electrode.

The nanowire channel may include carbon nano tube, and the nanowire is formed of a material selected from the group consisting of zinc oxide (ZnO), vanadium oxide (V₂O₅), gallium nitride (GaN), and aluminum nitride (AlN).

When electrons are majority carriers, the source/drain electrodes may be formed of a metal silicide having a low Schottky barrier height for the electrons, the metal silicide including a metal selected from the group consisting of erbium (Er), ytterbium (Yb), samarium (Sm), yttrium (Y), gadolinium (Gd), terbium (Tb), and cerium (Ce). When holes are majority carriers, the source/drain electrodes may include a metal silicide having a low Schottky barrier height for the holes, the metal silicide including a metal selected from the group consisting of platinum (Pt), lead (Pb), and iridium (Ir).

The gate insulation layer may include a material selected from the group consisting of silicon oxide, zirconium oxide (ZrO₂), hafnium oxide (HfO₂), and aluminum oxide (Al₂O₃). The substrate may be a bulk silicon substrate or a silicon-on-insulator (SOI) substrate.

In accordance with another aspect of the present invention, there is provided a method for fabricating a Schottky barrier nanowire field effect transistor may include the steps of: a) forming silicon layer patterns on a substrate; b) forming a channel of a nanowire, the channel being suspended over the substrate and having both ends contacting the silicon layer patterns; c) forming a source/drain region of metal silicide so that the source/drain region is electrically connected to the channel; d) forming a gate insulation layer surrounding the channel; and e) forming a gate electrode on the gate insulation layer.

The step of c) forming a source/drain region of metal silicide may include the steps of: c1) forming a metal layer over the substrate in which the channel is formed; c2) performing a thermal annealing to react the silicon layer pattern and the metal layer, thereby forming metal silicide; and c3) removing the metal layer that is not reacted in the thermal treatment. When electrons are majority carriers, the metal layer may be formed of a metal silicide having a low Schottky barrier height for the electrons, the metal silicide including a metal selected from the group consisting of erbium (Er), ytterbium (Yb), samarium (Sm), yttrium (Y), gadolinium (Gd), terbium (Tb), and cerium (Ce). When holes are majority carriers, the metal layer may be formed of a metal silicide having a low Schottky barrier height for the holes, the metal silicide including a metal selected from the group consisting of platinum (Pt), lead (Pb), and iridium (Ir).

The nanowire channel may include a carbon nano tube. The nanowire may be formed of a material selected from the group consisting of zinc oxide (ZnO), vanadium oxide (V₂O₅), gallium nitride (GaN), and aluminum nitride (AlN).

The method of claim 8, wherein the step of b) forming a channel of a nanowire may include the steps of: b1) forming a nanowire; b2) dispersing the nanowire in a solution; b3) transferring the dispersed nanowire over the silicon layer patterns; and b4) removing the solution. The step of b3) transferring the dispersed nanowire over the silicon layer patterns may be performed by a drop coating, a spin coating, a spray coating, or a dip coating.

The step of b) forming a channel of a nanowire may include the steps of: b1) forming a catalyst layer on the silicon layer patterns; b2) growing the nanowire from the catalyst layer by a chemical vapor deposition (CVD) process; and b3) removing the catalyst layer. The catalyst layer is formed of a material selected from the group consisting of Fe(NO₃)₃·9H₂O, MoO₂ (acac)₂, and alumina.

The gate insulation layer may be formed using a chemical vapor deposition (CVD) process or an atomic layer deposition (ALD) process. The gate insulation layer is formed of a material selected from the group consisting of silicon oxide, zirconium oxide (ZrO₂), hafnium oxide (HfO₂), and aluminum oxide (Al₂O₃). The gate electrode is formed using an angle evaporation process or a sputtering process.

Other objects and advantages of the present invention can be understood by the following description, and become apparent with reference to the embodiments of the present invention. Also, it is obvious to those skilled in the art to which the present invention pertains that the objects and advantages of the present invention can be realized by the means as claimed and combinations thereof.

### BRIEF DESCRIPTION OF THE DRAWINGS

FIG. 1A is a perspective view of a Schottky barrier nanowire FET in accordance with an embodiment of the present invention.

FIG. 1B is a cross-sectional view taken along line X-X′ of FIG. 1A.

FIGS. 2A, 3A, 4A, 5A and 6A are perspective views illustrating a method for fabricating a Schottky barrier nanowire FET in accordance with an embodiment of the present invention.

FIGS. 2B, 3B, 4B, 5B and 6B are cross-sectional views respectively taken along lines X-X′ of FIGS. 2A, 3A, 4A, 5A and 6A.

### DESCRIPTION OF SPECIFIC EMBODIMENTS

The advantages, features and aspects of the invention will become apparent from the following description of the embodiments with reference to the accompanying drawings, which is set forth hereinafter. In the drawings, the dimensions of layers and regions are exaggerated for clarity of illustration. It will also be understood that when a layer (or film) is referred to as being “on“another layer or substrate, it can be directly on the other layer or substrate, or intervening layers may also be present. Like reference numerals refer to like elements throughout the drawings.

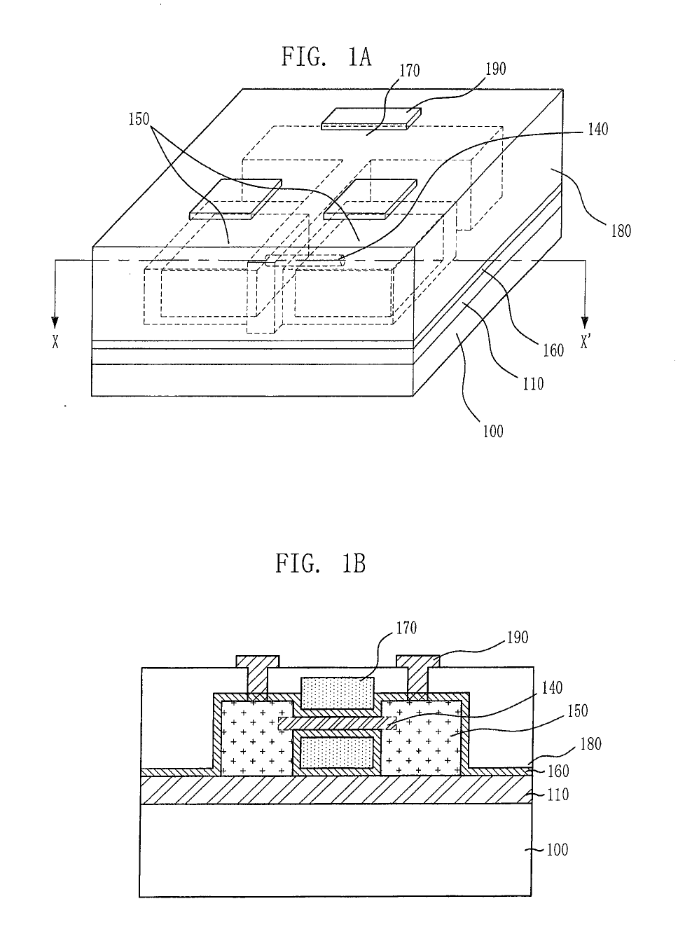

FIG. 1A is a perspective view of a Schottky barrier nanowire FET in accordance with an embodiment of the present invention, and FIG. 1B is a cross-sectional view taken along line X-X′ of FIG. 1A.

Referring to FIGS. 1A and 1B, the Schottky barrier nanowire FET includes a substrate 100, a channel 140 suspended over the substrate 100 and formed of a nanowire, source/drain electrodes 150 electrically connected to both ends of the channel 140 over the substrate 100 and formed of metal silicide, a gate electrode 170 surrounding the channel 140, and a gate insulation layer 160 disposed between the channel 140 and the gate electrode 170. The Schottky barrier nanowire FET may further include a passivation layer 180 disposed on the gate electrode 170 and the source/drain electrodes 150, and a contact layer 190 for electric connection with an external electrode.

The substrate 100 may be a bulk silicon substrate and an SOI substrate. Specifically, the SOI substrate can reduce a leakage current of a transistor and increase a driving current. The SOI substrate may include a support substrate 100 for mechanical support, a buried oxide layer 110 disposed on the support substrate 100, and a silicon layer disposed on the buried oxide layer 110.

The channel 140 may be formed of a nanowire, and examples of nanowire include carbon nano tube. The nanowire may be formed of a material having excellent junction characteristics to the source/drain electrodes 150 formed of metal silicide. For example, the nanowire may be formed of a material selected from the group consisting of zinc oxide (ZnO), vanadium oxide (V₂O₅), gallium nitride (GaN), and aluminum nitride (AlN). Especially, the carbon nano tube has 1000 times the maximum allowable current density of copper (Cu). Although the diameter of carbon nanotube is about 1 to 2 nm, the carbon nano tube has five times the mobility of silicon due to its ballistic transport property with no scattering and thus it has a high possibility that can be applied to the channel of the transistor.

The channel 140 is suspended over the substrate 100. This suspend structure can prevent the electric characteristic of the channel, i.e., nanowire from being degraded by mutual action between the substrate 100 and the nanowire when they are contacted with each together.

Due to the suspend structure, the channel 140 can be completely surrounded by the gate insulation layer 160 and the gate electrode 170. Such a structure can increase the contact area between the gate and the channel 140 and improve the gate controllability. Further, electric field produced by the gate can be effectively applied to the channel 140, thus improving the performance of the transistor. Furthermore, since the channel 140 is completely surrounded by the gate, a depletion region formed by the electric field is isolated from the substrate 100 and thus Iₒₙ/I_{off} is maximized.

The gate insulation layer 160 may be formed of a silicon oxide layer or a ferroelectric dielectric layer. The ferroelectric dielectric layer may be formed of a material selected from the group consisting of zirconium oxide (ZrO₂), hafnium oxide (HfO₂), and aluminum oxide (Al₂O₃).

The source/drain electrodes 150 may be formed of a conductive material, for example, metal silicide, which has an excellent stability in a thermal treatment. Metal silicide may be formed by reacting silicon (Si) with metal. Since metal silicide contains silicon, it can maintain a stable state even when the thermal treatment is performed at approximately 1,000° C. Therefore, when the channel 140 and the source/drain electrodes 150 are contacted with each other, a thermal stability can be ensured, thus obtaining a stable contact characteristic between them.

If the source/drain electrodes 150 are formed of metal silicide, a Schottky junction is formed between the channel 14 and the source/drain electrodes 150. In an N-type transistor where electrons are majority carriers, the source/drain electrodes 150 may be formed of a metal silicide having low Schottky barrier height for electrons, for example, the metal silicide including a metal selected from the group consisting of erbium (Er), ytterbium (Yb), samarium (Sm), yttrium (Y), gadolinium (Gd), terbium (Tb), and cerium (Ce). In a P-type transistor where holes are majority carriers, the source/drain electrodes 150 may be formed of a metal silicide having low Schottky barrier height for holes, for example, the metal silicide including a metal selected from the group consisting of platinum (Pt), lead (Pb), and iridium (Ir).

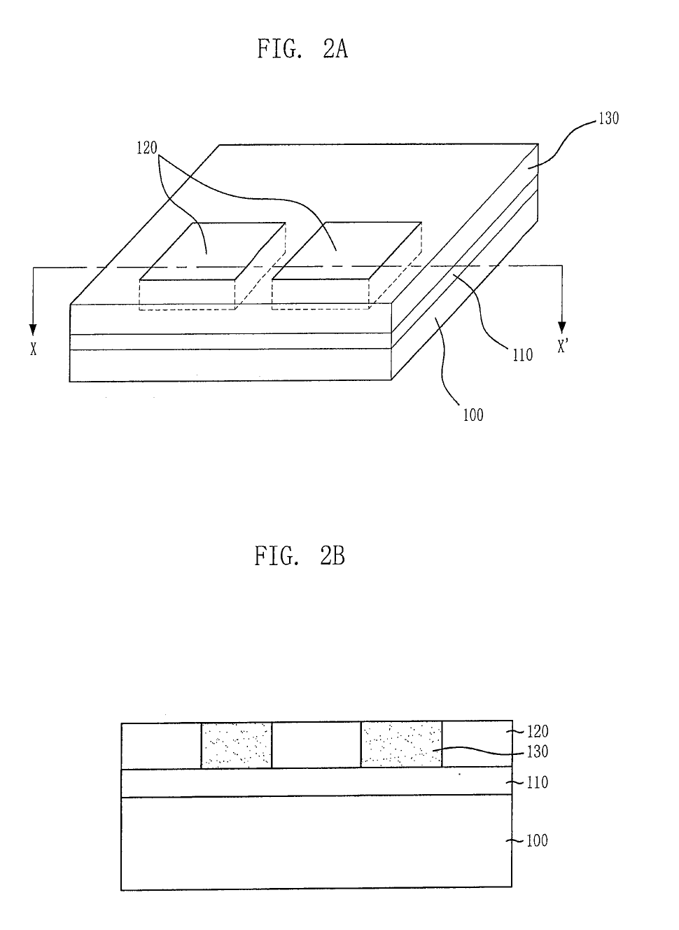

A method for fabricating a nanowire FET in accordance with an embodiment of the present invention will be described below with reference to FIGS. 2 to 6. In the following description, known technologies will be omitted and it should be understood that the technical scope of the present invention is not limited.

FIGS. 2A, 3A, 4A, 5A and 6A are perspective views illustrating a method for fabricating a Schottky barrier nanowire FET in accordance with an embodiment of the present invention, and FIGS. 2B, 3B, 4B, 5B and 6B are cross-sectional views respectively taken along lines X-X′ of FIGS. 2A, 3A, 4A, 5A and 6A.

Referring to FIGS. 2A and 2B, an SOI substrate is prepared. The SOI substrate may include a support substrate 100 for mechanical support, a buried oxide layer 110 formed on the support substrate 100, and a silicon layer formed on the buried oxide layer 110.

Photoresist patterns are formed on the silicon layer. Silicon layer patterns 120 are formed by etching the silicon layer using the photoresist pattern as an etch barrier. The silicon layer patterns 120 will be a source electrode and a drain electrode through subsequent processes. Therefore, the gap between the silicon layer patterns 120 can be adjusted considering the contact between the channel and the source/drain electrodes according to physical characteristics, such as length, width or tensile strength of the channel, i.e., the nanowire, which will be formed later. Preferably, the gap between the silicon layer patterns 120 is less than 100 nm.

A bulk silicon substrate can be used instead of the SOI substrate.

A sacrificial layer 130 is deposited over the resulting structure with the silicon layer patterns 120. Thereafter, the sacrificial layer 130 is planarized to expose the silicon layer patterns 120. The sacrificial layer 130 may be formed of photoresist, and the planarization process may be performed using a chemical mechanical polishing (CMP) process.

In the process of forming the channel, the sacrificial layer 130 prevents the formation of the channel with its both ends being not contacted with the silicon layer patterns 120 when the gap between the silicon layer patterns 120 is greater than 100 nm. If the channel contacts the substrate 100 without contacting both ends of the silicon layer patterns 120, the operation characteristics of the semiconductor device may be degraded and the semiconductor device may not operate normally.

When the gap between the silicon layer patterns 120, i.e., the gap between the source electrode and the drain electrode, is less than 100 nm, or when the channel can be suspended over the substrate 100 between the silicon layer patterns 120, the process of forming the sacrificial layer 130 and the planarization process can be omitted.

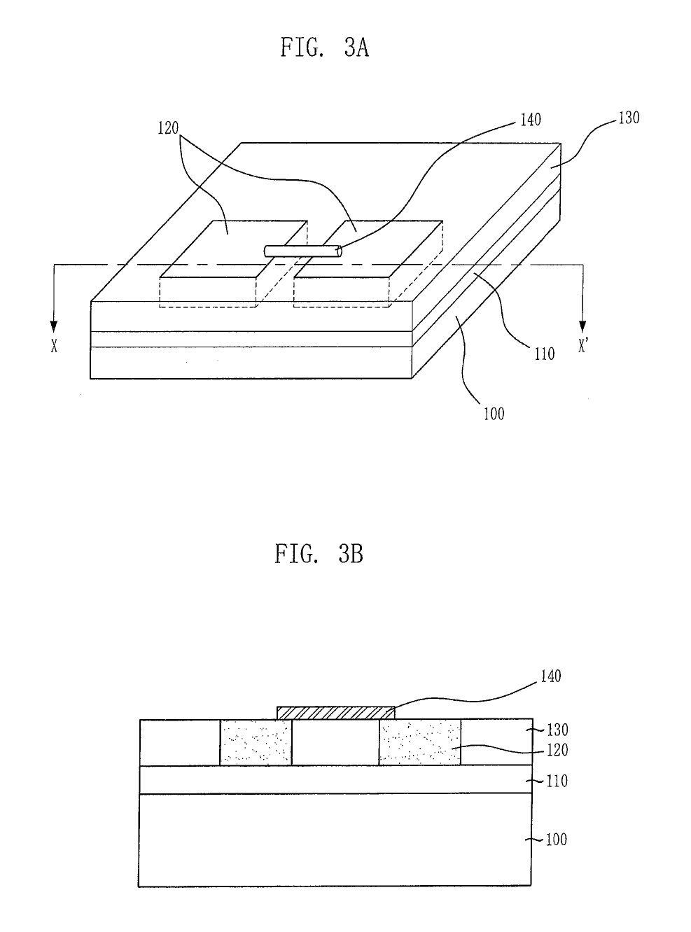

Referring to FIGS. 3A and 3B, the channel 140 is formed of a nanowire such that its both ends contact the silicon layer patterns 120. The nanowire may be formed of a material having excellent adhesion to the source/drain electrodes 150 formed of metal silicide. For example, the nanowire may be formed of a material selected from the group consisting of zinc oxide (ZnO), vanadium oxide (V₂O₅), gallium nitride (GaN), and aluminum nitride (AlN). Alternatively, the channel 140 may be formed of a carbon nano tube.

Hereinafter, the process of forming the channel 140 of the nanowire so that its both ends contact with the silicon layer patterns 120 will be described as one example.

The nanowire is formed using a chemical vapor deposition (CVD) process, a synthesis method using an arc, or a template method using anodic aluminum oxide or polycarbonate membrane polymer. Thereafter, the nanowire is separated and cleaned, and a solution is dispersed. A general organic solvent such as ethanol is used as a solvent. When the nanowire is not well dispersed due to a low solubility between the solvent and the nanowire, a physical impact such as ultrasonic wave may be applied for accelerating the dispersion of the nanowire. The solution in which the nanowire is dispersed is transferred over the silicon layer patterns 120 using a drop coating (dispensing), a spin coating, a spray coating, or a dip coating. A thermal treatment or a process of removing the solvent in a vacuum state may be performed to form the channel 140 with its both ends contacting the silicon layer patterns 120. In case where the nanowire dispersed into the solution is used, both ends of the nanowire may not contact the silicon layer patterns 120. To solve this problem, a post treatment may be further performed.

Another method for forming the channel 140 using a carbon nano tube will be described below.

A catalyst layer is formed on the silicon layer patterns 120. The catalyst layer may be formed of a material selected from the group consisting of Fe(NO₃)₃·9H₂O, MoO₂ (acac)₂, and alumina. A carbon nano tube is grown from the catalyst layer by controlling reaction conditions such as temperature or time using a CVD process. The carbon nano tube may be formed laterally, that is, in parallel to the substrate 100. In this way, the channel 140 with its both ends contacting the silicon layer patterns 120 can be formed of the carbon nano tube. Since the lateral growth technology of the carbon nano tube is known, its detailed description will be omitted. The catalyst layer is removed because it is unnecessary in a subsequent process of forming a source electrode and a drain electrode.

Through the above-described procedures, the nanowire channel 140 can be formed. Examples of the nanowire include carbon nano tube. The channel is formed with its both ends contacting the silicon layer patterns 120.

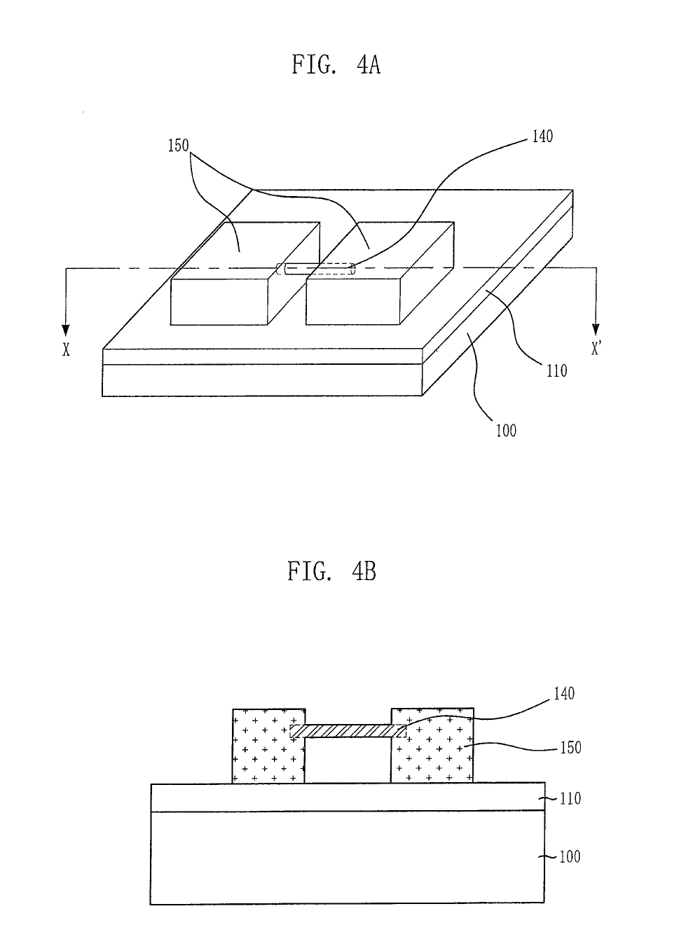

Referring to FIGS. 4A and 4B, a metal layer is formed over the resulting structure with the channel 140. The metal layer will be used for forming the source/drain electrodes 150 of metal silicide. The metal layer may be formed of transition metal or rare-earth metal.

In an N-type transistor where electrons are majority carriers, the metal layer may be formed of a metal silicide having low Schottky barrier height for electrons, for example, the metal silicide including a metal selected from the group consisting of erbium (Er), ytterbium (Yb), samarium (Sm), yttrium (Y), gadolinium (Gd), terbium (Tb), and cerium (Ce). In a P-type transistor where holes are majority carriers, the metal layer may be formed of a metal silicide having low Schottky barrier height for holes, for example, the metal silicide including a metal selected from the group consisting of platinum (Pt), lead (Pb), and iridium (Ir).

Thereafter, the sacrificial layer 130 is removed. Due to the removal of the sacrificial layer 130, the channel 140 can be suspended over the substrate 100.

A thermal treatment is performed for forming the source/drain electrodes 150 of metal silicide by reacting the silicon layer patterns 120 with the metal layer. The thermal treatment may be performed using a rapid thermal annealing (RTA) process, a furnace annealing process, or a laser annealing process. For example, when the source/drain electrodes 150 are formed of erbium silicide (ErSi), the RTA process is performed at a temperature ranging from approximately 500° C. to approximately 600° C.

Then, the metal layer that is not reacted in the thermal treatment is removed. The unreacted metal layer can be removed using a sulfuric peroxide mixture (SPM), which is a mixture of sulfuric acid (H₂SO₄) and hydrogen peroxide (H₂O₂), or an aqua regia, which is a mixture of hydrochloric acid (HCl) and nitric acid (HNO₃).

By forming the source/drain electrodes 150 of metal silicide, the channel 140 and the source/drain electrodes 150 can be electrically connected to each other. Compared with the source/drain electrodes formed of a metal, the source/drain electrodes 150 formed of metal silicide can ensure the higher thermal stability. Since metal silicide contains silicon, it can maintain a stable state even when a thermal treatment is performed at a temperature of approximately 1,000° C. The thermal stability makes it possible to ensure a stable contact characteristic when the source/drain electrodes 150 and the channel 140 are contacted with each other.

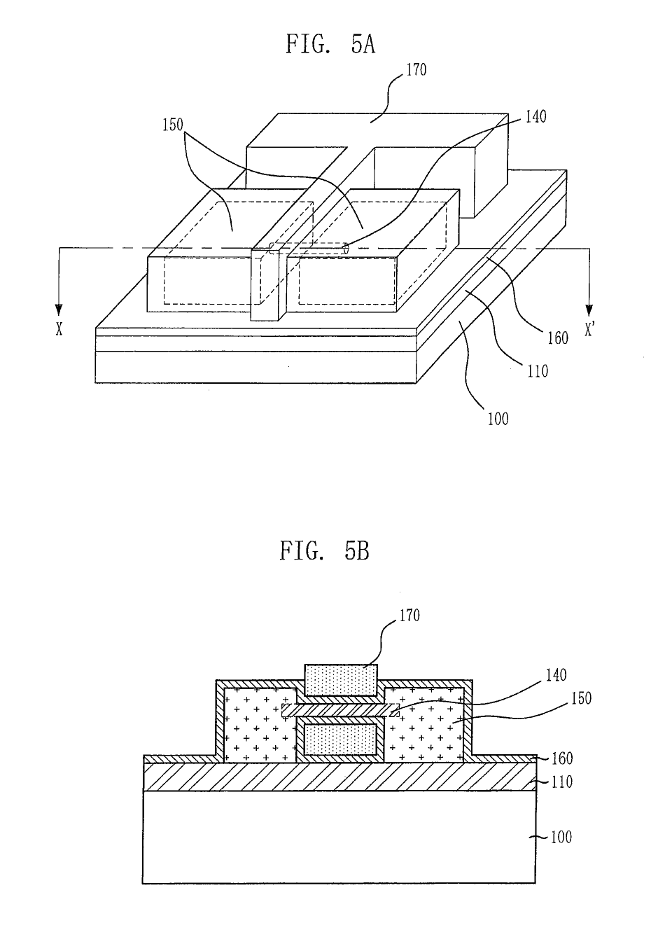

Referring to FIG. 5, a gate insulation layer 160 is deposited on the resulting structure with the channel 140 and the source/drain electrodes 150. The gate insulation layer 160 may be formed using a CVD process or an atomic layer deposition (ALD) process. Preferably, the gate insulation layer 160 is formed to completely surround the exposed channel 140. Thus, it is more preferable to use an ALD process having good step coverage.

The gate insulation layer 160 may be formed of a silicon oxide layer or a ferroelectric dielectric layer. The ferroelectric dielectric layer may be formed of a material selected from the group consisting of zirconium oxide (ZrO₂), hafnium oxide (HfO₂), and aluminum oxide (Al₂O₃).

A gate electrode 170 is formed on the gate insulation layer 160. More specifically, a photoresist pattern opening a gate region is formed and a gate conductive layer is deposited. The photoresist pattern is removed. Then, the gate conductive layer formed in an unnecessary region is removed using a lift-off process.

In order to form the gate electrode 170 completely surrounding the channel 140, the gate electrode 170 is primarily deposited in such a stat that the substrate is inclined at a specific angle. Then, the substrate is turned 90 degrees and the gate electrode 170 is secondarily deposited using an angle evaporation process or a sputtering process. Compared with the angle evaporation process, the sputtering process has an advantage in that the gate electrode can be deposited at a time because the straightness of metal particles is reduced and the channel 140 is thin.

The gate electrode 170 may be formed of a metal, for example, titanium (Ti), iron (Fe), or cobalt (Co).

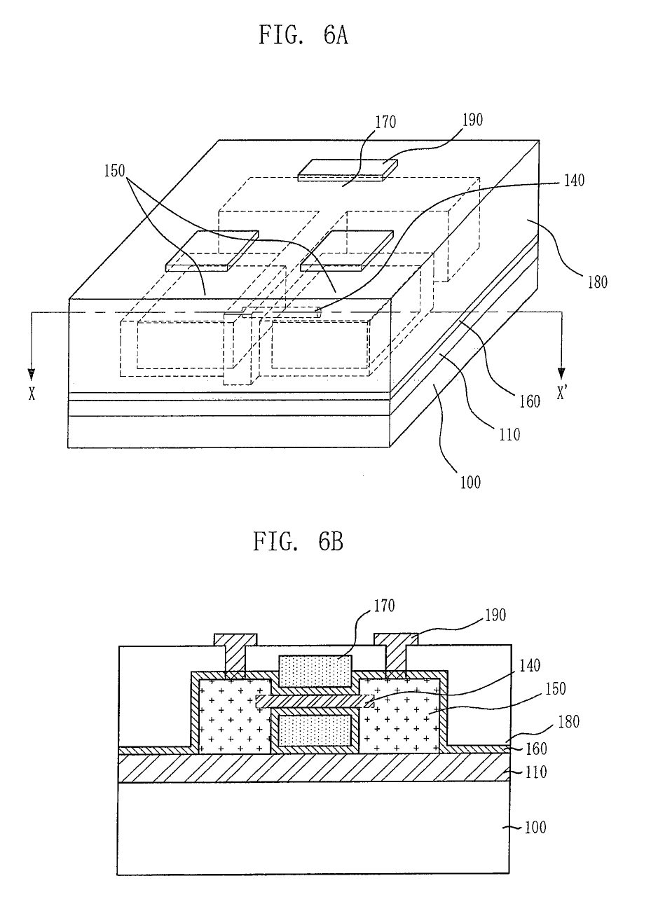

Referring to FIG. 6, a passivation layer 180 is formed for protecting the gate electrode 170 and the source/drain electrodes 150 from the outside. The passivation layer 180 may be formed of one selected from the group consisting of an oxide layer, a nitride layer, an oxynitride layer, a carbon-containing layer, and a stacked layer thereof. Examples of the oxide layer include a silicon oxide layer (SiO₂), a boron phosphorus silicate glass (BPSG), a phosphorus silicate glass PSG), a tetra ethyl ortho silicate (TEOS), an un-doped silicate glass (USG), a spin on glass (SOG), a high density plasma (HDP), and a spin on dielectric (SOD). Examples of the nitride layer include a silicon nitride layer (Si₃N₄). Examples of the carbon-containing layer include an amorphous carbon layer (ACL) and a carbon rich polymer.

Thereafter, a contact layer 190 is formed for electric connection with an external electrode. More specifically, the contact layer 190 is formed by selectively etching the passivation layer 180 and the gate insulation layer 160 to form a via hole opening the gate electrode 170 and the source/drain electrodes 150, and depositing a conductive layer, e.g., a polysilicon layer.

Through the above-described procedures, the Schottky barrier nanowire FET in accordance with the embodiment of the present invention is formed.

By forming the source/drain electrodes 150 of metal silicide, the thermal stability can be ensured in the contact between the channel 140 and the source/drain electrodes 150.

Further, since the channel 140 is suspended over the substrate 100, it can prevent the performance degradation of the Schottky barrier nanowire FET, which is caused by the mutual action between the substrate 100 and the channel 140.

Moreover, since the channel 140 is suspended over the substrate 100 and the channel 140 is completely surrounded by the gate, the controllability for the channel 140 can be improved.

Although the Schottky barrier nanowire FET has been exemplarily described above, the present invention can also be applied to semiconductor devices such as bio-sensors employing nanowire, e.g., carbon nano tube.

While the present invention has been described with respect to the specific embodiments, it will be apparent to those skilled in the art that various changes and modifications may be made without departing from the spirit and scope of the invention as defined in the following claims.

What is claimed is:

1. A Schottky barrier nanowire field effect transistor, comprising:
a nanowire channel suspended over a substrate;
metal silicide source/drain electrodes electrically connected to both ends of the channel over the substrate;
a gate electrode disposed to surround the channel; and
a gate insulation layer disposed between the channel and the gate electrode.

2. The Schottky barrier nanowire field effect transistor of claim 1, wherein the nanowire includes a material selected from the group consisting of zinc oxide (ZnO), vanadium oxide (V₂O₅), gallium nitride (GaN), and aluminum nitride (AlN).

3. The Schottky barrier nanowire field effect transistor of claim 1, wherein the nanowire channel includes a carbon nano tube.

4. The Schottky barrier nanowire field effect transistor of claim 1, wherein when electrons are majority carriers, the source/drain electrodes include a metal silicide having a low Schottky barrier height for the electrons, the metal silicide including a metal selected from the group consisting of erbium (Er), ytterbium (Yb), samarium (Sm), yttrium (Y), gadolinium (Gd), terbium (Tb), and cerium (Ce).

5. The Schottky barrier nanowire field effect transistor of claim 1, wherein when holes are majority carriers, the source/drain electrodes include a metal silicide having a low Schottky barrier height for the holes, the metal silicide including a metal selected from the group consisting of platinum (Pt), lead (Pb), and iridium (Ir).

6. The Schottky barrier nanowire field effect transistor of claim 1, wherein the gate insulation layer includes a material selected from the group consisting of silicon oxide, zirconium oxide (ZrO₂), hafnium oxide (HfO₂), and aluminum oxide (Al₂O₃).

7. The Schottky barrier nanowire field effect transistor of claim 1, wherein the substrate is a bulk silicon substrate or a silicon-on-insulator (SOI) substrate.

8. A method for fabricating a Schottky barrier nanowire field effect transistor, comprising the steps of:
a) forming silicon layer patterns on a substrate;
b) forming a channel of a nanowire, the channel being suspended over the substrate and having both ends contacting the silicon layer patterns;
c) forming a source/drain region of metal silicide so that the source/drain region is electrically connected to the channel;
d) forming a gate insulation layer surrounding the channel; and
e) forming a gate electrode on the gate insulation layer.

9. The method of claim 8, wherein the step c) includes the steps of:
c1) forming a metal layer over the substrate in which the channel is formed;
c2) performing a thermal annealing to react the silicon layer pattern and the metal layer, thereby forming metal silicide; and
c3) removing the metal layer that is not reacted in the thermal annealing.

10. The method of claim 9, wherein when electrons are majority carriers, the metal layer is formed of a metal silicide having a low Schottky barrier height for the electrons, the metal silicide including a metal selected from the group consisting of erbium (Er), ytterbium (Yb), samarium (Sm), yttrium (Y), gadolinium (Gd), terbium (Tb), and cerium (Ce).

11. The method of claim 9, wherein when holes are majority carriers, the metal layer is formed of a metal silicide having a low Schottky barrier height for the holes, the metal silicide including a metal selected from the group consisting of platinum (Pt), lead (Pb), and iridium (Ir).

12. The method of claim 8, wherein the nanowire is formed of a material selected from the group consisting of zinc oxide (ZnO), vanadium oxide (V₂O₅), gallium nitride (GaN), and aluminum nitride (AlN).

13. The method of claim 8, wherein the nanowire channel includes carbon nano tube.

14. The method of claim 8, wherein the step b) includes the steps of:
b1) forming a nanowire;
b2) dispersing the nanowire in a solution;
b3) transferring the dispersed nanowire over the silicon layer patterns; and
b4) removing the solution.

15. The method of claim 14, wherein the step b3) is performed by a drop coating, a spin coating, a spray coating, or a dip coating.

16. The method of claim 8, wherein the step b) includes the steps of:
b1) forming a catalyst layer on the silicon layer patterns;
b2) growing the nanowire from the catalyst layer by a chemical vapor deposition (CVD) process; and
b3) removing the catalyst layer.

17. The method of claim 16, wherein the catalyst layer is formed of a material selected from the group consisting of Fe(NO₃)₃·9H₂O, MoO₂ (acac)₂, and alumina.

18. The method of claim 8, wherein the gate insulation layer is formed using a chemical vapor deposition (CVD) process or an atomic layer deposition (ALD) process.

19. The method of claim 8, wherein the gate insulation layer is formed of a material selected from the group consisting of silicon oxide, zirconium oxide (ZrO₂), hafnium oxide (HfO₂), and aluminum oxide (Al₂O₃).

20. The method of claim 8, wherein the gate electrode is formed using an angle evaporation process or a sputtering process.
